(19) United States
(12) Patent Application Publication
(10) Pub. No.: US 2025/0208190 A1
(43) Pub. Date: Jun. 26, 2025

(54) TITLE DIRECT FLUID COOLING WITH MULTI TEMPERATURE CONTROL

(71) Applicant: INTEL CORPORATION, Santa Clara, CA (US)

(72) Inventors: Craig YOST, Gilbert, AZ (US); Paul DIGLIO, Gaston, OR (US); Gregorio R. MURTAGIAN, Phoenix, AZ (US); Christopher Wade ACKERMAN, Phoenix, AZ (US)

(21) Appl. No.: 18/393,488

(22) Filed: Dec. 21, 2023

(51) Int. Cl. G01R 31/26

(52) U.S. Cl. CPC G01R 31/2642

(57) ABSTRACT

In some embodiments, provided are test apparatuses suitable for operation in semiconductor environmental testing chambers that can provide both first fluid (e.g., hot fluid) and second fluid (cold fluid) delivery without requiring a complete teardown of the utilized assembly.

### TECHNICAL FIELD

Embodiments of the invention relate to the field of semiconductor testing apparatuses; and more specifically, to fluid delivery assemblies for controlling the temperature of a device under test.

### BRIEF DESCRIPTION OF THE DRAWINGS

The disclosure may best be understood by referring to the following description and accompanying drawings that are used to illustrate embodiments of the invention. In the drawings:

FIG. 1 is a diagram showing a conventional testing device for direct fluid temperature management.

FIGS. 2A-2C are diagrams illustrating a test apparatus for providing both first and second fluid options within an environmental test chamber in accordance with some embodiments.

FIGS. 3A-3C are diagrams illustrating a fluid delivery assembly in accordance with some embodiments.

FIGS. 4A and 4B are diagrams depicting a fluid delivery assembly in hot and cold modes, respectively, in accordance with some embodiments.

FIGS. 5A and 5B depict an alternative fluid delivery assembly embodiment employing a multi-position actuator in accordance with some embodiments.

FIGS. 6A and 6B are diagrams showing an alternate fluid delivery approach in accordance with some embodiments.

### DETAILED DESCRIPTION

Direct fluid temperature management for device under test (DUT) temperature control during testing is becoming ever more challenging with DUTs incorporating advanced process integrated circuits (ICs) and IC packages that can have extreme thermal densities. While the use of direct fluid impingement can be effective in more quickly, and evenly, managing DUT temperatures, it also poses challenges in testing over full temperature ranges.

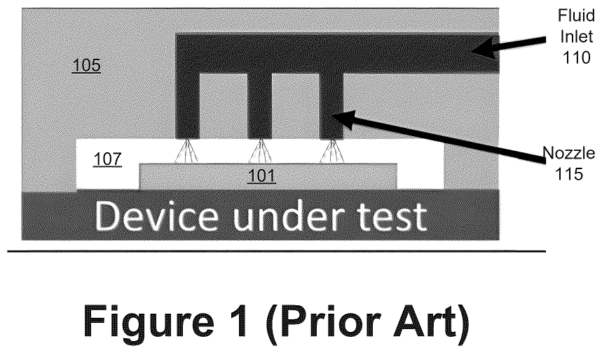

FIG. 1 shows a conventional testing device 105 for direct fluid temperature management of a device under test (DUT) 101 in an environmentally controllable (e.g., pressure, temperature) chamber 107, The test apparatus has a fluid inlet 110 and nozzles 115 for directing a temperature control fluid such as water onto the DUT 101. Unfortunately, the nozzle configurations are fixed, making it very difficult to change between hot and cold temperature testing fluids. For among other reasons, because hot and cold fluid applications typically involve using differently sized and/or shaped nozzles, e.g., in order to switch between cold and hot test fluids, different assembly mechanisms are generally required. This can significantly add to equipment expense, as well as the time needed to perform comprehensive testing due to assembly conversion delays. Accordingly, in some embodiments, provided are test apparatuses suitable for operation in semiconductor environmental testing chambers that can provide both first fluid (e.g., hot fluid) and second fluid (cold fluid) delivery without requiring a complete teardown of the utilized assembly.

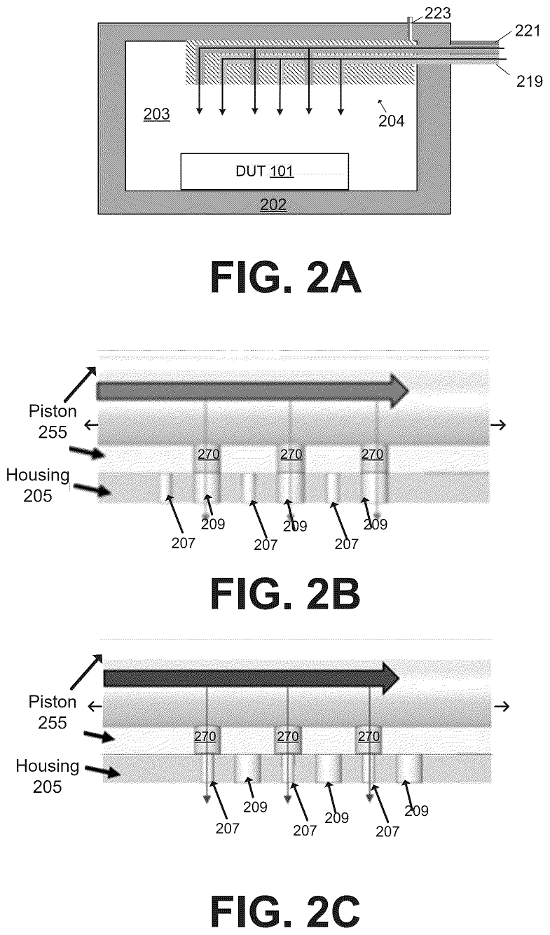

FIGS. 2A-2C are diagrams illustrating a test apparatus 202 for providing both first and second fluid options within an environmental test chamber 203 in accordance with some embodiments. The depicted test apparatus 202 includes a fluid delivery assembly 204 having a housing 205 with both hot and cold fluid inlets (219, 221) for applying a selected one of the fluid options onto the DUT 101. It also includes an actuation port 223 for controlling a controllable fluid gate, in this embodiment, a piston 255, to control fluid selection to either hot nozzles 207 or cold nozzles 209. As is illustrated, the nozzles may have differently sized openings in order to facilitate single phase direct heat transfer (e.g., cooling) and/or two-phase direct heat transfer (e.g., cooling. The first and second fluid options, for convenience, are referred to as “cold” and “hot” since this may be a common application of the first and second fluid delivery options, but this will not necessarily always be the case. The cold and hot options could, for example, convey fluids of similar temperatures but applied differently (e.g., single or two phase), or they could constitute different fluid types.

The controllable fluid delivery gate (piston in this case) may be controlled using any suitable method such as with a pneumatic or electric actuator. Similarly, while a piston is shown, any suitable controllable fluid delivery gate mechanism such as a moveable piston, slidable plate insert, levered valves, or the like, could be used. (As used herein, the term piston refers to any controllably moveable, in a reciprocating manner, vessel that is capable of channeling temperature management fluids such as water to one or more nozzle openings. It may have two fixed positions, or it may have multiple position options, depending on the actuator used to drive it, as well as on the housing used to define its available positions. In addition, it may have any suitable cross-sectional shape such as circular, elliptical, rectangular, triangular, etc. In fact, in some embodiments, it may have a somewhat flattened fluid delivery surface to more readily couple with the nozzle openings for efficiently conveying fluid therethrough. Similarly, it may be capable of holding within its structure the fluid without substantial leakage or alternatively, it may simply be used to convey vessels such as tubes or the like contained within to be positioned over a selected set of nozzle openings.)

FIG. 2B shows the piston 255 in a cold fluid position. Its fluid outflow ports 270 are aligned with the cold nozzle openings 209 and block the hot nozzle openings 207, allowing fluid flow through the cold nozzle openings. In contrast, FIG. 2C shows the piston 255 in a hot fluid position. Its fluid outflow ports 270 are aligned with the hot nozzle openings 207 and block the cold nozzle openings 209, allowing flow through the hot nozzle openings. Note that for the cold fluid, a larger nozzle opening size is used in a 1-phase DUT direct fluid impingement, while narrower nozzle openings are used for the hot fluid, but it is also possible to use a single phase nozzle size for the hot fluid as well. However, for improved heat transfer performance, a smaller nozzle opening size for two-phase direct fluid impingement may be desired.

It should be appreciated that the terms “cold” and “hot” are relative. Specific temperatures will depend on particular factors such as the target temperature for the DUT, desired temperature change rates, DUT structural tolerances, etc. In some embodiments, a cold fluid may refer to the use of a single-phase fluid application with the fluid being at any desired temperature. Likewise, in some embodiments, a hot fluid may refer to a fluid used in a two-phase cooling scheme. This is not required, however, either or both of the cold and hot fluid options may be used for single or two phase cooling, or heating, for that matter.

Two-phase change properties of fluids can be used to enable high density cooling. In some scenarios, the working fluid may be put under a controlled vacuum to regulate the amount of cooling power possible. In addition, the working fluid may be preheated to near or above the intended target temperature of the DUT further reducing the amount of time needed for the fluid to boil on the surface. Thus, heat transfer performance can be more flexibly controlled by controlling fluid conditions including fluid flow, incoming fluid temperature and fluid environment pressure in addition to other optimization details to maximize surface area of the heat-exchange area on both the DUT and working fluid. In some two-phase cooling embodiments, the fluid may be heated to a few degrees above the intended DUT target temperature (boiling point of the fluid at a specific vacuum level), and the fluid is sprayed onto the die using, for example, a minimal flow-rate necessary to prevent dry-out. It should also be appreciated that while application of cold and hot fluids have primarily been discussed in terms of cooling, they also may be used for heating DUTs, which may be desired in some testing scenarios.

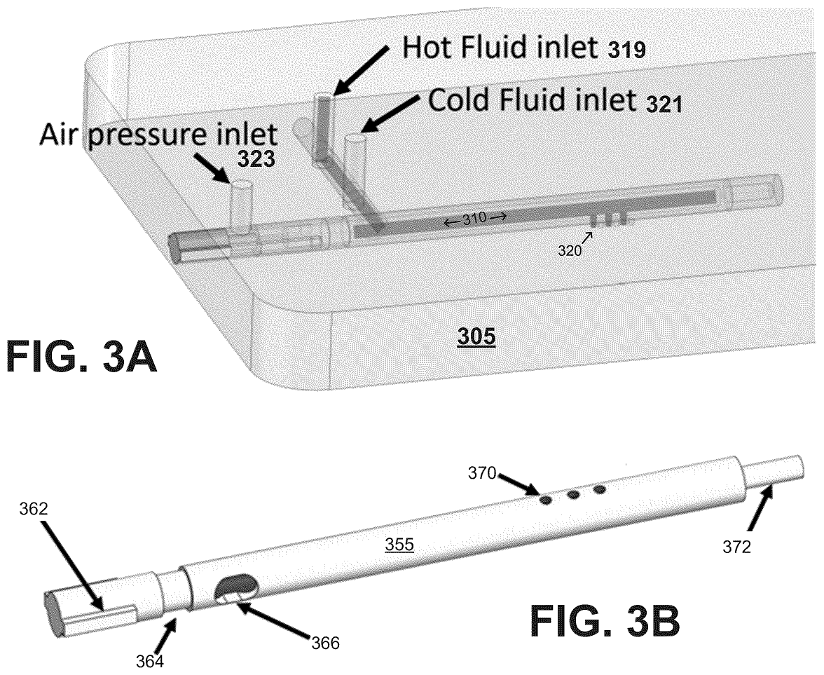

FIGS. 3A-3C are diagrams illustrating a fluid delivery assembly in accordance with some embodiments. FIG. 3A is a top perspective view of a housing 305 for an assembly using a reciprocating piston for fluid control. The housing, which may be formed of any suitable material such as stainless steel or aluminum or a composite with favorable tolerances to temperatures used for testing, may be employed. It may be formed from machining, molding, or any other suitable process given the utilized material.

The housing 305 has a channel 310, fluid delivery port 316, nozzle openings 320, a hot fluid inlet 319, a cold fluid inlet 321, and a pneumatic gas inlet (air in the depicted FIG. 323. The channel 310 houses a piston 355, an example of which is shown in FIG. 3B. The hot and cold inlets (319, 321) are configured to receive appropriate fluid supplies (e.g., temperature controlled hot and cold water, respectively) and deliver either one, depending on which is applied at the time, into the piston through fluid delivery port 316 (FIG. 3C). The pneumatic gas inlet is coupled to a controllable suitably pressurized gas source (e.g., pressurized air) to control the position of the piston 355. The nozzle openings 320 are configured to function as nozzles, or to connect with nozzle fixtures (not shown) to project the selected fluid option (e.g., cold or hot) from the underside of the housing and onto the device under test (DUT).

FIG. 3B is a perspective view showing an embodiment of a piston 355 for use with the housing 305 of FIG. 3A. The piston 310 generally includes stabilizer guides 362, a seal portion 364, a fluid intake port 366, fluid outflow ports 370, and spring portion 372. The stabilizer guide 362 fits into a slot for stabilizing the position to prevent it from rolling and misaligning with the outflow ports 370 with respect to nozzle openings 320. The seal (e.g., gasket) portion 364 receives around it a fitted seal to prevent pneumatic gas (e.g., air) from the pneumatic actuation chamber, when pressurized, from leaking into the piston. The fluid intake port 366 receives the provided fluid (hot or cold) from an inlet port (319, 321) whereupon it enters the piston and flows out of the outlet ports 370 through either the hot nozzle openings or cold nozzle openings, depending on the position of the piston.

FIG. 3C is another perspective view of the housing 305 from FIG. 3A. In this diagram, stabilizer slots 312 for guiding the piston stabilizer guides 362 are shown. There is also indicated a fluid inlet channel 318 that conveys fluid, either from the hot (319) or cold (321) inlets to the inlet port 316. Also shown is a seal portion, which receives a seal to block air from entering the piston, and a spring portion 322. The spring portion 322 not only receives a spring, which, in cooperation with the pneumatic actuator, facilitates the two reciprocating positions of the piston, but also, it accommodates the spring portion 372, which has a smaller diameter than the main piston portion, allowing the piston to slide forward and backward within a longitudinal bored section (not shown).

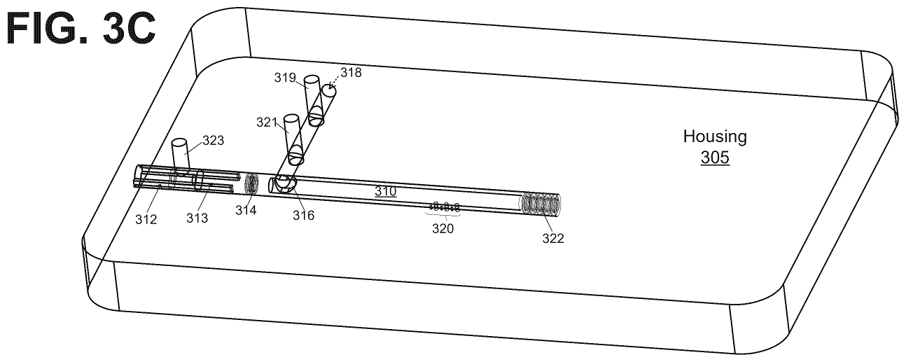

FIGS. 4A and 4B are diagrams depicting the fluid delivery assembly in hot and cold fluid modes, respectively, in accordance with some embodiments. In FIG. 4A, the assembly 304 is in a position to provide hot fluid out of the hot nozzle openings 327 with the fluid outflow ports 370 aligned therewith. For this mode, the pneumatic inlet 323 is off, not providing air pressure to the actuation chamber 311, which enables spring 374 to force the piston against the pneumatic chamber wall and align the outflow ports 370 with the hot nozzle openings 327. Conversely, when the pneumatic actuator is activated and air is pressurized into chamber 311, the piston moves against the spring, pushing it until it is fully compressed or until the piston makes contact with a detent defined by the housing. In this position, the piston outflow ports 370 are aligned with the larger cold nozzle openings 329 to release fluid (e.g., cold fluid out of the nozzles.

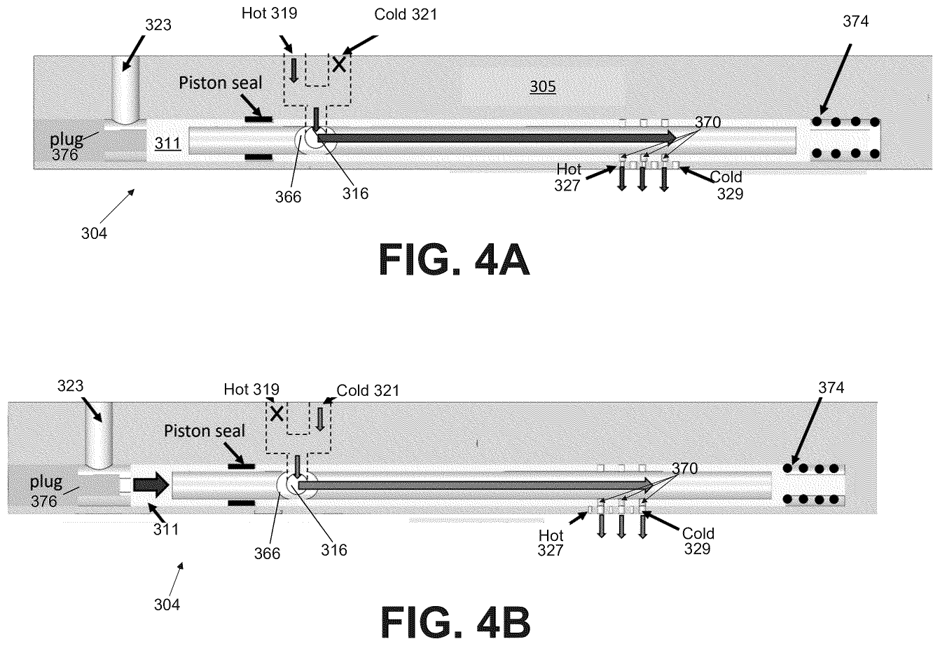

FIGS. 5A and 5B depict an alternative fluid delivery assembly embodiment employing a multi-position actuator in accordance with some embodiments. The depicted assembly comprises an electrical actuator (e.g., geared mechanism deterministically driven by an electrical actuator such as a stepper motor or the like) for precise piston positioning. With this approach, a set of nozzle openings 520 having the same, fixed sizes may be used. However, their effective sizes are modified using the actuator to control how much of the fluid outflow openings 570 overlap the nozzle openings 520. For a single phase cold fluid application, the actuator could control the gates to be fully open and for hot, two-phase fluid applications, the nozzle openings may be more restricted to adjust fluid to modulate the heat transfer coefficient for the device under test, as is illustrated in FIG. 5B. This has a benefit in that the same nozzle impingement locations on the DUT surface may be maintained.

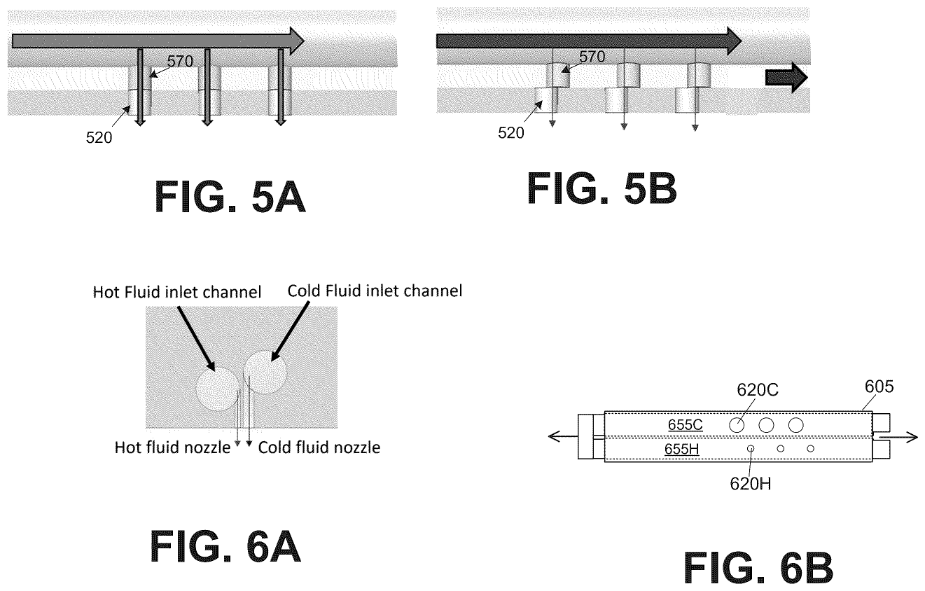

FIGS. 6A and 6B are diagrams showing an alternate fluid delivery approach using separate inlet channels for hot and cold fluids in accordance with some embodiments. For example, a piston or other reciprocating member having two parallel fluid chambers could be used. This is illustrated in FIG. 6B, a top schematic view showing dual fluid pistons 655C and 655H for hot and cold fluids, respectfully. The nozzle openings 620C, 620H, along with their corresponding outflow ports from the dual pistons, are staggered, relative to each other so that the pistons can be controlled together, as a single unit. In a first position, e.g., with a pneumatic actuator activated (as indicated in FIG. 6B), the hot openings and outflow ports are aligned, while in the other position, with the pistons pushed leftward against the actuator wall, the cold openings and ports are aligned. In this way, hot and cold fluids could be supplied together to the assembly, avoiding the need to replace one for the other or otherwise have to switch between them from the supply inlets.

Illustrative examples of the technologies disclosed herein are provided below. An embodiment of the technologies may include any one or more, and any compatible combination of, the examples described below.

Example 1 is an apparatus that includes a housing and a fluid delivery gate. The housing has a fluid delivery channel, first and second fluid inlets, and first and second pluralities of nozzle openings. The fluid delivery gate is controllably slidable within the housing channel to deliver a fluid from a selected one of the first and second fluid inlets to a selected one of the first and second pluralities of nozzle openings, wherein the housing is operable within a semiconductor environmental test chamber.

Example 2 includes the subject matter of example 1, and wherein the housing includes nozzles mounted to the nozzle openings.

Example 3 includes the subject matter of any of examples 1 and 2, and wherein the first plurality of nozzle openings are larger in area than the second plurality of nozzle openings.

Example 4 includes the subject matter of any of examples 1-3, and wherein the first plurality of nozzle openings are interleaved with the second plurality of nozzle openings.

Example 5 includes the subject matter of any of examples 1-4, and further comprises an actuator to control the position of the fluid delivery gate.

Example 6 includes the subject matter of any of examples 1-5, and wherein the actuator is a pneumatic actuator.

Example 7 includes the subject matter of any of examples 1-6, and wherein the actuator is an electrical actuator to control the fluid delivery gate position to be in one of three or more different positions to control the size of the second plurality of nozzle openings.

Example 8 includes the subject matter of any of examples 1-7, and wherein the fluid delivery gate is a piston.

Example 9 includes the subject matter of any of examples 1-8, and comprises a pneumatic actuator and a spring to control the piston to be in a first position to deliver fluid to the first plurality of nozzle openings or in a second position to deliver fluid to the second plurality of nozzle openings.

Example 10 includes the subject matter of any of examples 1-9, and wherein the piston includes first and second chambers, the first chamber coupled to the first fluid inlet and the second chamber coupled to the second fluid inlet.

Example 11 includes the subject matter of any of examples 1-10, and wherein the piston has a flat fluid delivery surface.

Example 12 includes the subject matter of any of examples 1-11, and wherein the piston has a rectangular cross-sectional shape.

Example 13 includes the subject matter of any of examples 1-12, and wherein the fluid delivery gate is a slidable plate having holes to be aligned with a selected one of the first and second pluralities of nozzle openings to deliver fluid thereto.

Example 14 is a testing system that includes a test apparatus and a fluid delivery assembly. The test apparatus has a pressure and temperature controllable chamber for testing a device under test (DUT). The fluid delivery assembly is in the test apparatus to project first and second fluids onto the DUT. The fluid delivery assembly includes a housing having a fluid delivery channel, a first fluid inlet to receive the first fluid, a second fluid inlet to receive the second fluid, and first and second pluralities of nozzle openings. It also has a fluid delivery gate that is controllably slidable within the housing channel to deliver a selected one of the first and second fluids to a selected one of the first and second pluralities of nozzle openings,

Example 15 includes the subject matter of example 14, and wherein the housing includes nozzles mounted to the nozzle openings.

Example 16 includes the subject matter of any of examples 14-15, and wherein the first plurality of nozzle openings are larger in area than the second plurality of nozzle openings.

Example 17 includes the subject matter of any of examples 14-16, and wherein the first plurality of nozzle openings are interleaved with the second plurality of nozzle openings.

Example 18 includes the subject matter of any of examples 14-17, and further comprising an actuator within the housing to control the position of the fluid delivery gate.

Example 19 includes the subject matter of any of examples 14-18, and wherein the actuator is a pneumatic actuator.

Example 20 includes the subject matter of any of examples 14-19, and wherein the actuator is an electrical actuator to control the fluid delivery gate position to be in one of three or more different positions to control the size of the second plurality of nozzle openings.

Example 21 includes the subject matter of any of examples 14-20, and wherein the fluid delivery gate is a piston.

Example 22 includes the subject matter of any of examples 14-21, and comprising a pneumatic actuator and a spring to control the piston to be in a first position to deliver fluid to the first plurality of nozzle openings or in a second position to deliver fluid to the second plurality of nozzle openings.

Example 23 includes the subject matter of any of examples 14-22, and wherein the piston includes first and second chambers, the first chamber coupled to the first fluid inlet and the second chamber coupled to the second fluid inlet.

Example 24 includes the subject matter of any of examples 14-23, and wherein the piston has a flat fluid delivery surface.

Example 25 includes the subject matter of any of examples 14-24, and wherein the piston has a rectangular cross-sectional shape.

Example 26 includes the subject matter of any of examples 14-25, and wherein the fluid delivery gate is a slidable plate having holes to be aligned with a selected one of the first and second pluralities of nozzle openings to deliver fluid thereto.

Example 27 is an apparatus that includes a housing and a controllably movable piston. The housing has a first fluid inlet to receive a first fluid, a second fluid inlet to receive a second fluid, and a plurality of nozzle openings positioned to control the temperature of a device under test (DUT) through direct fluid impingement of the first or second fluids out of the nozzle openings. The controllably moveable piston is slidable within the housing to couple the first or second fluid inlets to the plurality of nozzle openings and to control the sizes of the nozzle openings.

Example 28 includes the subject matter of example 27, and wherein the housing includes nozzles mounted to the nozzle openings.

Example 29 includes the subject matter of any of examples 27-28, and further comprising an actuator to control the position of the piston.

Example 30 includes the subject matter of any of examples 27-29, and wherein the actuator is an electrical actuator to control the piston position to be in one of three or more different positions to control the effective size of the second plurality of nozzle openings.

Example 31 includes the subject matter of any of examples 27-30, and wherein the piston has lateral stabilizer guides to radially stabilize it.

Example 32 includes the subject matter of any of examples 27-31, and wherein the piston includes first and second chambers, the first chamber coupled to the first fluid inlet and the second chamber coupled to the second fluid inlet.

Example 33 includes the subject matter of any of examples 27-32, and wherein the piston has a flat fluid delivery surface.

Example 34 includes the subject matter of any of examples 27-33, and wherein the piston has a rectangular cross-sectional shape.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, or magnetic connection between the things that are connected or an indirect connection, through one or more passive or active intermediary devices.

The meaning of “in” includes “in” and “on” unless expressly distinguished for a specific description.

The terms “substantially,” “close,” “approximately,” “near,” and “about,” unless otherwise indicated, generally refer to being within +/−10% of a target value.

Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

It is pointed out that those elements of the figures having the same reference numbers (or names) as the elements of any other figure can operate or function in any manner similar to that described but are not limited to such.

As defined herein, the term “if” means “when” or “upon” or “in response to” or “responsive to,” depending upon the context. Thus, the phrase “if it is determined” or “if [a stated condition or event] is detected” may be construed to mean “upon determining” or “in response to determining” or “upon detecting [the stated condition or event]” or “in response to detecting [the stated condition or event]” or “responsive to detecting [the stated condition or event]” depending on the context. As defined herein, the term “responsive to” means responding or reacting readily to an action or event. Thus, if a second action is performed “responsive to” a first action, there is a causal relationship between an occurrence of the first action and an occurrence of the second action. The term “responsive to” indicates the causal relationship.

While the flow diagrams in the figures show a particular order of operations performed by certain embodiments of the invention, it should be understood that such order is exemplary (e.g., alternative embodiments may perform the operations in a different order, combine certain operations, overlap certain operations, etc.).

While the invention has been described in terms of several embodiments, those skilled in the art will recognize that the invention is not limited to the embodiments described, can be practiced with modification and alteration within the spirit and scope of the appended claims. The description is thus to be regarded as illustrative instead of limiting.

What is claimed is:

1. An apparatus, comprising:
a housing having a fluid delivery channel, first and second fluid inlets, and first and second pluralities of nozzle openings; and
a fluid delivery gate that is controllably slidable within the housing channel to deliver a fluid from a selected one of the first and second fluid inlets to a selected one of the first and second pluralities of nozzle openings, wherein the housing is operable within a semiconductor environmental test chamber.

2. The apparatus of claim 1, wherein the housing includes nozzles mounted to the nozzle openings.

3. The apparatus of claim 1, wherein the first plurality of nozzle openings are larger in area than the second plurality of nozzle openings.

4. The apparatus of claim 3, wherein the first plurality of nozzle openings are interleaved with the second plurality of nozzle openings.

5. The apparatus of claim 1, further comprising an actuator to control the position of the fluid delivery gate.

6. The apparatus of claim 5, wherein the actuator is a pneumatic actuator.

7. The apparatus of claim 1, wherein the fluid delivery gate is a piston.

8. The apparatus of claim 7, comprising a pneumatic actuator and a spring to control the piston to be in a first position to deliver fluid to the first plurality of nozzle openings or in a second position to deliver fluid to the second plurality of nozzle openings.

9. The apparatus of claim 7, wherein the piston includes first and second chambers, the first chamber coupled to the first fluid inlet and the second chamber coupled to the second fluid inlet.

10. The apparatus of claim 7, wherein the piston has a flat fluid delivery surface.

11. A testing system, comprising:
a test apparatus having a pressure and temperature controllable chamber for testing a device under test (DUT); and
a fluid delivery assembly mounted in the test apparatus to project first and second fluids onto the DUT, the fluid delivery assembly including:
a housing having a fluid delivery channel, a first fluid inlet to receive the first fluid, a second fluid inlet to receive the second fluid, and first and second pluralities of nozzle openings, and
a fluid delivery gate that is controllably slidable within the housing channel to deliver a selected one of the first and second fluids to a selected one of the first and second pluralities of nozzle openings.

12. The system of claim 11, wherein the first plurality of nozzle openings are larger in area than the second plurality of nozzle openings.

13. The system of claim 12, wherein the first plurality of nozzle openings are interleaved with the second plurality of nozzle openings.

14. The system of claim 11, further comprising an actuator to control the position of the fluid delivery gate.

15. The system of claim 11, wherein the fluid delivery gate is a piston.

16. The system of claim 15, wherein the piston includes first and second chambers, the first chamber coupled to the first fluid inlet and the second chamber coupled to the second fluid inlet.

17. An apparatus, comprising:
a housing having a first fluid inlet to receive a first fluid, a second fluid inlet to receive a second fluid, and a plurality of nozzle openings positioned to control the temperature of a device under test (DUT) through direct fluid impingement of the first or second fluids out of the nozzle openings; and
a controllably moveable piston that is slidable within the housing to couple the first or second fluid inlets to the plurality of nozzle openings and to control the sizes of the nozzle openings.

18. The apparatus of claim 17, wherein the housing includes nozzles mounted to the nozzle openings.

19. The apparatus of claim 17, further comprising an actuator to control the position of the piston.

20. The apparatus of claim 17, wherein the piston includes first and second chambers, the first chamber coupled to the first fluid inlet and the second chamber coupled to the second fluid inlet.
